(19) United States
(12) Patent Application Publication
(10) Pub. No.: US 2013/0169557 A1
(43) Pub. Date: Jul. 4, 2013

(54) WIRING SUBSTRATE AND METHOD OF MANUFACTURING THE SAME

(71) Applicant: Jae Hong KIM, Seoul (KR)

(72) Inventor: Jae Hong KIM, Seoul (KR)

(21) Appl. No.: 13/596,132

(22) Filed: Aug. 28, 2012

(30) Foreign Application Priority Data
Dec. 29, 2011 (KR) 10-2011-0146144

(51) Int. Cl. H05K 1/02; H05K 3/00; G06F 3/041

(52) U.S. Cl. 345/173; 174/250; 427/97.3; 427/511

(57) ABSTRACT

The wiring substrate includes a substrate; a plurality of conductive patterns on a surface of the substrate, the plurality of conductive patterns including a plurality of sensing electrodes, a plurality of driving electrodes and a plurality of wirings connected to at least one of the plurality of sensing electrodes and the plurality of driving electrodes; and a photo solder resist layer on the surface of the substrate, the photo solder resist layer including a body and a plurality of protrusions extending from a side of the body, wherein an end portion of each protrusion is formed on each of the respective wirings, and a width of the end portion is smaller than a width of a starting portion of each protrusion that is in contact with the side of the body.

### CROSS-REFERENCE TO RELATED APPLICATIONS

This application claims the benefit of Korean Patent Application No. 10-2011-0146144, filed on Dec. 29, 2011, which is hereby incorporated by reference for all purposes as if fully set forth herein.

### BACKGROUND OF THE INVENTION

1. Field of the Invention

The present invention relates to a wiring substrate and a method of manufacturing the same, and more particularly, to a wiring substrate that uses a photo solder resist layer as an insulating layer, and a method of manufacturing the wiring substrate.

2. Discussion of the Related Art

With the development of electronic engineering technology and information technology (IT), the importance of electronic devices in daily lives and work environment is increasing steadily, and various types of electronic devices are thus becoming in demand. Accordingly, various forms of wiring substrates, which include wiring structures for delivering diverse signals on a substrate, are being widely used.

A wiring substrate includes wirings made of a conductive material and an insulating layer insulating the wirings from other elements. The insulating layer made of an insulating material can be formed by a silkscreen printing method. When the silkscreen printing method is used to form an insulating layer of a wiring substrate, a screen (e.g., a fabric or paper having holes formed in a mesh shape) is used.

However, the silkscreen printing method typically accompanies a low degree of accuracy in the patterns of the insulating layer, thereby increasing the defect rate and reducing the yield of the wiring substrate.

### SUMMARY OF THE INVENTION

Accordingly, the present invention is directed to a wiring substrate and a method of manufacturing the same that substantially obviates one or more of the problems due to limitations and disadvantages of the related art.

An advantage of the present invention is to provide a wiring substrate that uses a photo solder resist layer as an insulating layer to increase the accuracy of the patterns of the insulating layer, and a method of manufacturing the wiring substrate.

Additional features and advantages of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described, a touch screen device having a wiring substrate, the wiring substrate may include a substrate; a plurality of conductive patterns on a surface of the substrate, the plurality of conductive patterns including a plurality of sensing electrodes, a plurality of driving electrodes and a plurality of wirings connected to at least one of the plurality of sensing electrodes and the plurality of driving electrodes; and a photo solder resist layer on the surface of the substrate, the photo solder resist layer including a body and a plurality of protrusions extending from a side of the body, wherein an end portion of each protrusion is formed on each of the respective wirings, and a width of the end portion is smaller than a width of a starting portion of each protrusion that is in contact with the side of the body.

In another aspect of the present invention, a method of manufacturing a touch screen device having a wiring substrate, the method may include forming a plurality of conductive patterns on a surface of a substrate, the plurality of conductive patterns including a plurality of sensing electrodes and a plurality of wirings connected to the plurality of sensing electrodes; and forming a photo solder resist layer on the surface of the substrate, the photo solder resist layer including a body and a plurality of protrusions extending from a side of the body, wherein an end portion of each protrusion is formed on each of the respective wirings, and a width of the end portion is smaller than a width of a starting portion of each protrusion that is in contact with the side of the body.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a top view of a wiring substrate according to an embodiment of the present invention;

FIG. 2 is a cross-sectional view taken along line II-IF of FIG. 1;

FIG. 3 is an enlarged view of region ‘A’ shown in FIG. 1;

FIG. 4 is a diagram illustrating a tensile force of a photo solder resist layer;

FIGS. 5 and 6 are enlarged views of region ‘A’ shown in FIG. 1 according to embodiments of the present invention;

FIG. 7 is a cross-sectional view taken along II-II′ of FIG. 1 according to another embodiment of the present invention;

FIG. 8 is a top view of a wiring substrate according to another embodiment of the present invention;

FIG. 9 is a cross-sectional view taken along line IX-IX′ of FIG. 8;

FIG. 10 is an enlarged view of region ‘A’ shown in FIG. 8; and

FIG. 11 is a flowchart illustrating a method of manufacturing a wiring substrate according to an embodiment of the present invention.

### DETAILED DESCRIPTION OF THE ILLUSTRATED EMBODIMENTS

Reference will now be made in detail to exemplary embodiments of the present invention, examples of which are illustrated in the accompanying drawings.

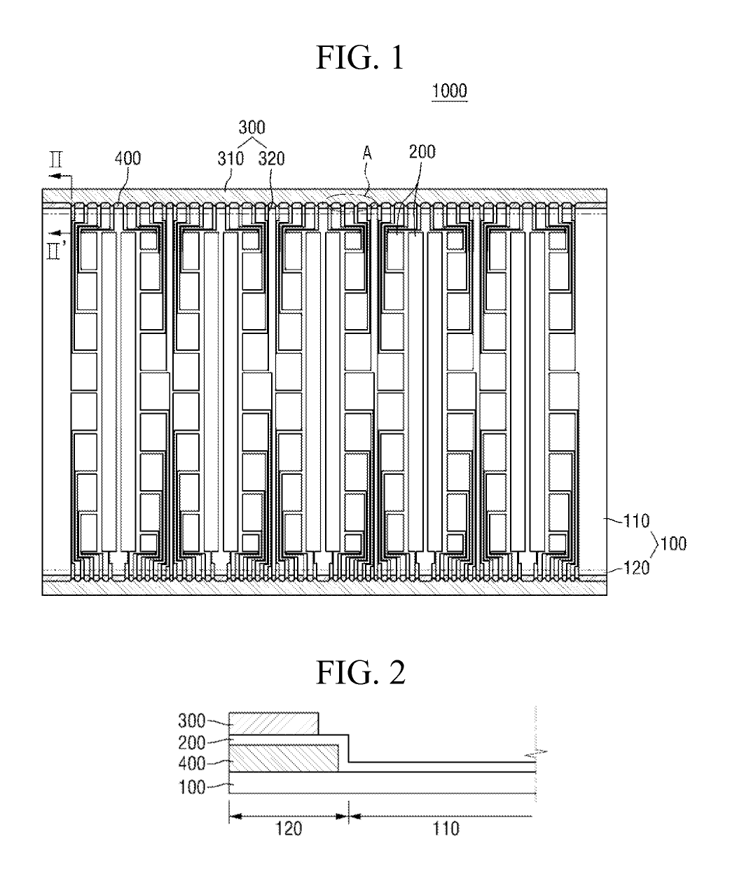

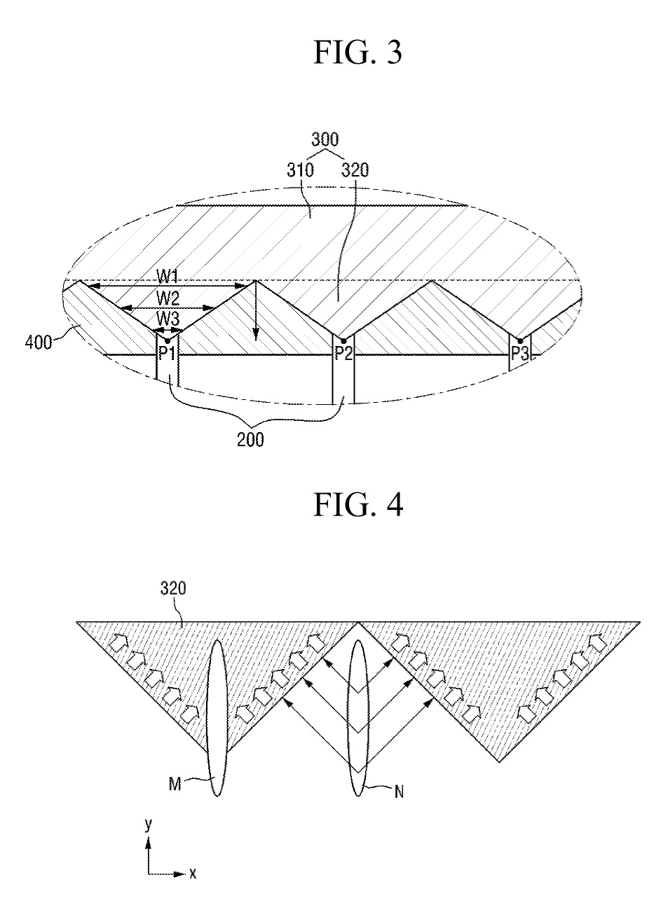

FIG. 1 is a top view of a wiring substrate 1000 according to an embodiment of the present invention. FIG. 2 is a cross-sectional view taken along line II-IF of FIG. 1. FIG. 3 is an enlarged view of region ‘A’ shown in FIG. 1. FIG. 4 is a diagram illustrating a tensile force of a photo solder resist layer 300.

Referring to FIGS. 1 through 3, the wiring substrate 1000 includes a substrate 100, one or more printed layers 400, a plurality of conductive patterns 200, and the photo solder resist layer 300.

The substrate 100 supports the printed layers 400, the conductive patterns 200 and the photo solder resist layer 300. When the wiring substrate is used for a touch screen device, the substrate 100 may be a transparent substrate. When the substrate 100 is a transparent substrate, it may be made of a high-strength material such as tempered glass or acrylic resin or a hard material applicable to flexible displays, such as polyethylene terephthalate (PET), polycarbonate (PC), polyethersulfone (PES), polyimide (PI), polymethyl methacrylate (PMMA), or the like.

The substrate 100 may be a cover glass applied to a touch screen device. In this case, the cover glass may be made of tempered glass or a high-strength plastic material. Typically, the substrate 100 is formed to a thickness of 0.3 T or greater so as to have a protective function.

A surface of the substrate 100 may include a first region 110 located in the center thereof and a second region 120 located in the periphery of the first region 110. In FIG. 1, the second region 120 is located on upper and lower sides of the first region 110. However, the second region 120 can also be located on left and right sides of the first region 110. In some embodiments, the second region 120 may surround the first region 110.

When the wiring substrate 1000 is used for a display device, the first region 110 may be a display region on which a picture or image is displayed, and the second region 120 may be a non-display region on which no picture or image is displayed. In addition, when the wiring substrate 1000 is used for a touch screen device, the first region 110 may be a touch sensing region that receives a user's touch input, and the second region 120 may be a region that includes wiring patterns for delivering signals to the first region 110 or delivering signals generated by the first region 110. Although the substrate 100 is divided into the first region 110 and the second region 120 for ease of description, the first region 110 and the second region 120 can also be integrated into a single region.

One or more printed layers 400 may be disposed on the surface of the substrate 100. Specifically, referring to FIGS. 1 and 2, one or more printed layers 400 may be disposed on the second region 120 of the surface of the substrate 100. As described above, the second region 120 may be a non-display region when the wiring substrate 1000 is used for a display device, or may be a region which includes wiring patterns, etc., when the wiring substrate 1000 is used for a touch screen device. In other words, the second region 120 is a region that a user does not need to see. To hide the wiring patterns in the second region 120, one or more printed layers 400 may thus be formed on the second region 120. In some embodiments, the printed layers 400 may be made of an opaque material.

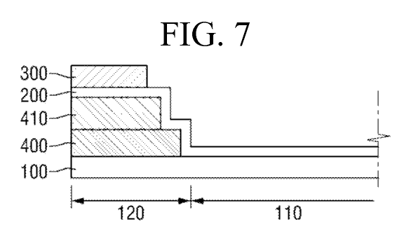

For ease of description, a single printed layer 400 is illustrated in FIGS. 1 through 3. However, a plurality of printed layers 400 can also be formed to more completely hide the wiring patterns, etc. For example, a first printed layer 400 and a second printed layer 410 may be formed in the second region 120, as illustrated in FIG. 7.

As the number of the printed layers 400 stacked on the surface of the substrate 100 increases, a step difference from a non-printed region increases. If the conductive patterns 200 are later formed in a region where such a step difference exists, defects such as a breaking of the conductive patterns 200 may increase. Generally, the step difference formed by the printed layers 400 may be approximately 1 to 100 μm.

The conductive patterns 200 may be disposed on the surface of the substrate 100. When the wiring substrate 1000 according to the current embodiment is used for a display device or touch screen device, the conductive patterns 200 may be made of a transparent conductive material. Examples of an applicable transparent conductive material include oxides such as indium tin oxide (ITO), indium zinc oxide (IZO) and zinc oxide (ZO), carbon nanotubes, metal nanowires, conductive polymers, or the like. A thickness of the conductive patterns 200 may vary depending on the transparent conductive material, but may be approximately 10 nm to 10 μm.

The conductive patterns 200 may be formed integrally on the surface of the substrate 100 by sputtering a transparent conductive material on the surface of the substrate 100 and then etching the transparent conductive material along the shape of the conductive patterns 200. For example, a transparent conductive material such as ITO may be sputtered on the surface of the substrate 100 at approximately 130 to 150° C. and then etched along the shape of the conductive patterns 200, thereby forming the conductive patterns 200.

When the wiring substrate 1000 according to the current embodiment is used for a touch screen device, the conductive patterns 200 may include sensing electrodes, driving electrodes, and/or wiring patterns that deliver sensing signals from the sensing electrodes or deliver driving signals to the driving electrodes. In FIG. 1, the conductive patterns 200 has a combination of bars, patches and lines. However, it would be appreciated that the sensing electrodes, the driving electrodes and the wiring patterns can have various shapes. For example, the conductive patterns 200 may have a shape disclosed in Korean Patent Application No. 10-2007-0021332, entitled “Touch Location Detecting Panel Having a Simple Layer Structure” and filed on Mar. 7, 2007, which is incorporated by reference in the present application.

The conductive patterns 200 may be disposed on the surface of the substrate 100 and on the second region 120 of the surface of the substrate 100. For example, when the conductive patterns 200 have sensing electrodes and wiring patterns as illustrated in FIG. 1, the sensing electrodes, which generate sensing signals in response to a user's touch, may be placed in the first region 110. The wiring patterns extending from the sensing electrodes may be placed in the first region 110 and the second region 120.

In a case where the wiring substrate 1000 is used as a cover glass, the wiring substrate 1000 may have a structure disclosed in Korean Patent Application No. 10-2008-0083724, entitled “Touch Sensing Panel Including Window Having Electrodes Formed Therewith as One Body, and Manufacturing Method Thereof” and filed on Aug. 27, 2008, which is incorporated by reference in the present application. To hide wiring parts and flexible printed circuit board (FPBC) connectors that are typically formed on a surface of the cover glass, one or more printed layers may be formed on edges of the surface of the cover glass. When wiring patterns are formed directly on the cover glass, ends of the wiring patterns are disposed in regions in which the printed layers are formed. In this case, the step difference formed by the printed layers is a factor that selects and concentrates various physical forces.

The photo solder resist layer 300, which can function as an insulating layer, may be formed on the surface of the substrate 100. Specifically, the photo solder resist layer 300 may be formed to cover a portion of the conductive patterns 200, as illustrated in FIGS. 1 and 2. In some embodiments, the photo solder resist layer 300 may be formed on the second region 120 of the surface of the substrate 100.

A process of forming the photo solder resist layer 300 as an insulating layer will be described. Materials (such as an oxide) that adversely affect the adhesion between the surface of the substrate 100 and photo solder resist ink may be removed. Then, the photo solder resist layer 300 may be formed by a front-surface process for forming roughness, a printing process for coating the photo solder resist ink on the surface of the substrate 100, a pre-cure process for removing a solvent of the photo solder resist ink to eliminate an adhesiveness, an exposure process for curing the resist by irradiating ultraviolet (UV) light to desired portions of the photo solder resist ink, a development process for removing portions that are not polymerized with the UV exposure by dissolving a developing solution, and finally a post-cure process for curing epoxy resin contained in the photo solder resist ink. The photo solder resist ink can be any conventional ink.

A via hole may be formed in the finally cured photo solder resist layer 300. As described above, the photo solder resist layer 300 functions as an insulating layer. Thus, the photo solder resist layer 300 may insulate wirings disposed thereon and thereunder. However, a via hole may be formed in the photo solder resist layer 300 to connect the wirings disposed on and under the photo solder resist layer 300, and another wiring may be formed to traverse the via hole. As a result, a bus line having a double-layered structure may be formed using the via hole. The via hole may be formed after the photo solder resist layer 300 is formed. Alternatively, the via hole and the photo solder resist layer 300 may be formed simultaneously.

The process of forming the photo solder resist layer 300 may additionally include a UV cure process after the post-cure process.

Referring to FIG. 3, the photo solder resist layer 300 may include a body 310 and a plurality of protrusions 320 that protrude from a side of the body 310. The protrusions 320 may have a triangular shape. As the distance from the side of the body 310 increases (in a direction indicated by an arrow extending from the side of the body 310 in FIG. 3), a width of the protrusions 320 may decrease (W1>W2>W3).

The protrusions 320 of the photo solder resist layer 300 may correspond to the conductive patterns 200, respectively. For example, three protrusions 320 may correspond to three conductive patterns 200, respectively, as illustrated in FIG. 3. Herein, each protrusion 320 may be formed on a region of the corresponding conductive pattern 200. Therefore, the number of the protrusions 320 may be equal to the number of the conductive patterns 200 disposed on the second region 120.

A vertex point of each protrusion 320, which is separated from the side of the body 310 by the longest distance, may be located on a region of the corresponding conductive pattern 200. For example, referring to FIG. 3, a vertex point P1 on the leftmost protrusion 320, which is separated from the side of the body 310 by the longest distance, may be located on a region of the corresponding conductive pattern 200. A vertex point P2 on the center protrusion 320, which is separated from the side of the body 310 by the longest distance, may be located on a region of the corresponding conductive pattern 200. Similarly, a vertex point P3 on the rightmost protrusion 320, which is separated from the side of the body 310 by the longest distance, may be located on a region of the corresponding conductive pattern 200.

As mentioned above, the wiring substrate 1000 according to the current embodiment uses the photo solder resist layer 300 as an insulating layer. When the photo solder resist layer 300 is formed as an insulating layer, the accuracy of the patterns of the insulating layer can be increased with a reduced defect rate as compared with the insulating layer that is formed by a silkscreen printing method. As discussed above, the silkscreen printing method typically accompanies a low degree of accuracy in the patterns of the insulating layer, thereby increasing the defect rate and reducing the yield of the wiring substrate.

Photo solder resist ink may contract during the curing process and generate tension when forming the photo solder resist layer 300 as an insulating layer. In the current embodiment, the pre-cure process is performed for a short period time, e.g., about 10 minutes or less at approximately 80 to 130° C. Therefore, the pre-cure process may not create a significant tension. Also, because the UV cure process is performed after the post-cure process, it may not cause the photo solder resist ink to contract significantly. However, because the post-cure process is performed for about 20 minutes or more at approximately 130° C. or above, most contraction of the photo solder resist layer 300 occurs during the post-cure process.

Referring to FIG. 2, the contraction of the photo solder resist layer 300 may generate a tension toward outside the substrate 100 (i.e., toward the left side of FIG. 2.) The generated tension of the photo solder resist layer 300 may also affect the conductive patterns 200 that are formed on the printed layers 400 and contact the photo solder resist layer 300. Accordingly, the conductive patterns 200, especially step portions of the conductive patterns 200, may break due to the generated tension. In this regard, the photo solder resist layer 300 of the wiring substrate 1000 according to the current embodiment may include the body 310 and the protrusions 320 that protrude from a side of the body 310. In addition, the protrusions 320 may be formed on the respective conductive patterns 200. When the post-cure process is performed on the photo solder resist layer 300, the tension generated during the curing of the photo solder resist layer 300 may be at the minimum level in the protrusions 320 and at the maximum level in the recessed portions between the protrusions 320.

More specifically, referring to FIG. 4, in M regions of the protrusions 320, a tensile force in an x-axis direction is at the minimum level, because pulling forces acting in opposite directions are offset by each other. In addition, a tensile force in a y-axis direction is reduced as compared with the case where the photo solder resist layer 300 is formed linearly, without any protrusions. However, in N regions in which the recessed portions between the protrusions 320 are located, a tensile force in the x-axis direction is at the maximum level, because puling forces acting in opposite directions are not offset by each other. In the current embodiment, the photo solder resist layer 300 includes the protrusions 320 that are formed on the conductive patterns 200 to reduce the tension acting on the conductive patterns 200, thereby minimizing or preventing the conductive patterns 200 from breaking.

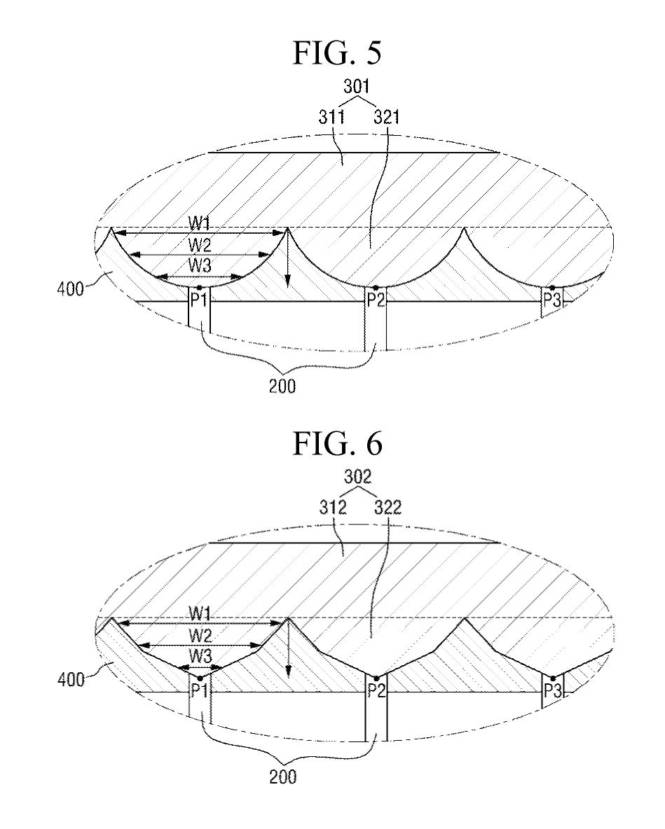

FIGS. 5 and 6 are enlarged views of region ‘A’ shown in FIG. 1 according to various embodiments of the present invention. Referring to FIGS. 5 and 6, a plurality of protrusions 321 or 322 of a photo solder resist layer 301 or 302 may have various shapes, for example, a polygonal or semicircular shape.

Referring to FIG. 5, the protrusions 321 of the photo solder resist layer 301 have a semicircular shape. In some embodiments, the protrusions 321 may be semi-elliptical. As the distance from a side of a body 311 increases (in a direction indicated by an arrow extending from the side of the body 311 in FIG. 5), a width of the protrusions 321 may decrease (W1>W2>W3). In addition, a vertex point P1, P2 or P3 of each protrusion 321, which is separated from the side of the body 311 by the longest distance, may be located on a region of the corresponding conductive pattern 200. The protrusions 321 of FIG. 5 are identical to the protrusions 320 of FIG. 3, except that they are semicircular, and thus a repetitive description thereof will be omitted.

Referring to FIG. 6, the protrusions 322 of the photo solder resist layer 302 have a polygonal shape. As the distance from a side of a body 312 increases (in a direction indicated by an arrow extending from the side of the body 312 in FIG. 6), a width of the protrusions 322 may decrease (W1>W2>W3). In addition, a vertex point P1, P2 or P3 of each protrusion 322, which is separated from the side of the body 312 by the longest distance, may be located on a region of the corresponding conductive pattern 200. The protrusions 322 of FIG. 6 are identical to the protrusions 320 of FIG. 3, except that they are polygonal, and thus a repetitive description thereof will be omitted.

The wiring substrate 1000 according to the current embodiment is described with examples in which it is used for a display device or touch screen device with reference to FIGS. 1 through 7. However, the present invention is not limited to these examples. The wiring substrate 1000 can be used for various devices that can utilize all types of wiring substrates on which wiring patterns and an insulating layer are placed.

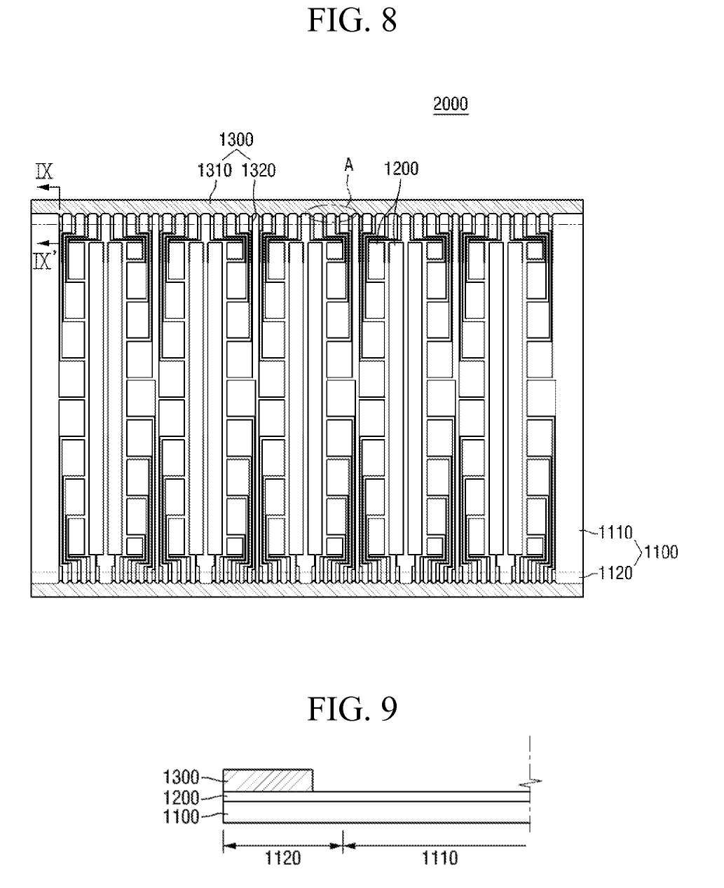

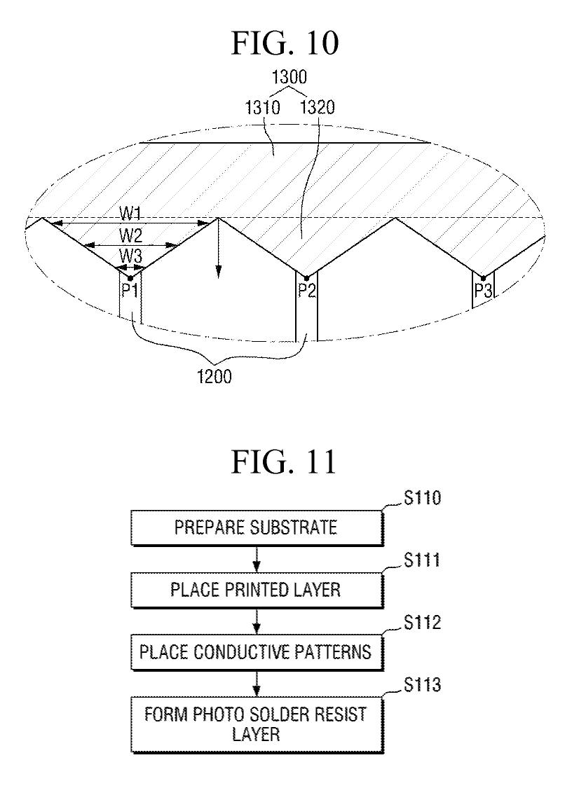

FIG. 8 is a top view of a wiring substrate 2000 according to another embodiment of the present invention. FIG. 9 is a cross-sectional view taken along line IX-IX′ of FIG. 8. FIG. 10 is an enlarged view of region ‘A’ shown in FIG. 8.

Referring to FIGS. 8 through 10, the wiring substrate 2000 includes a substrate 1100, a plurality of conductive patterns 1200, and a photo solder resist layer 1300. The wiring substrate 2000 is substantially identical to the wiring substrate 1000 of FIGS. 1 through 3, except that one or more printed layers are not disposed on a second region 1120 of a surface of the substrate 1100. Thus, a repetitive description thereof will be omitted.

FIG. 11 is a flowchart illustrating a method of manufacturing a wiring substrate according to an embodiment of the present invention.

In the method of manufacturing a wiring substrate according to the current embodiment, a substrate is first prepared (operation S110). The substrate is substantially identical to the substrate of FIGS. 1 through 10, and thus a repetitive description thereof will be omitted. One or more printed layers may then be placed on a second region of a surface of the substrate (operation S111). The printed layers are substantially identical to the printed layers of FIGS. 1 through 3, and thus a repetitive description thereof will be omitted.

Next, a plurality of conductive patterns are placed on the surface of the substrate (operation S112). The placing of the conductive patterns includes placing the conductive patterns on the printed layers disposed on the second region of the surface of the substrate. The conductive patterns are substantially identical to the conductive patterns of FIGS. 1 through 10, and thus a repetitive description thereof will be omitted.

Next, a photo solder resist layer that includes a body and a plurality of protrusions extending from a side of the body is formed on the surface of the substrate and the conductive patterns (operation S113). A process for forming the photo solder resist layer may include forming the photo solder resist layer on the second region of the surface of the substrate. The photo solder resist layer is substantially identical to the photo solder resist layer of FIGS. 1 through 10, and thus a repetitive description thereof will be omitted.

The process for forming the photo solder resist layer may include forming the protrusions that become narrower as the distance from the side of the body of the photo solder resist layer increases. The body and protrusions of the photo solder resist layer have substantially the same shape as the body and the protrusions of the photo solder resist layer of FIGS. 1 through 10, and thus a repetitive description thereof will be omitted.

The process for forming the photo solder resist layer may include forming the protrusions on the respective conductive patterns. In addition, the process for forming the protrusions on the conductive patterns may include forming a vertex point of each protrusion, which is separated from the side of the body by the longest distance, on the corresponding conductive pattern. The positional relationship between the photo solder resist layer and the conductive patterns is substantially identical to the positional relationship between the photo solder resist layer and the conductive patterns in FIGS. 1 through 10, and thus a repetitive description thereof will be omitted.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A touch screen device having a wiring substrate, the wiring substrate comprising:
a substrate;
a plurality of conductive patterns on a surface of the substrate, the plurality of conductive patterns including a plurality of sensing electrodes, a plurality of driving electrodes and a plurality of wirings connected to at least one of the plurality of sensing electrodes and the plurality of driving electrodes; and
a photo solder resist layer on the surface of the substrate, the photo solder resist layer including a body and a plurality of protrusions extending from a side of the body,
wherein an end portion of each protrusion is formed on each of the respective wirings, and a width of the end portion is smaller than a width of a starting portion of each protrusion that is in contact with the side of the body.

2. The touch screen device of claim 1, wherein the surface of the substrate comprises a first region located in a center portion of the substrate and a second region located in a periphery of the first region, and wherein the photo solder resist layer is formed on the second region.

3. The touch screen device of claim 2, further comprising a printed layer on the second region of the substrate, wherein the end portion of each protrusion is formed on the printed layer.

4. The touch screen device of claim 2, wherein the second region surrounds the first region.

5. The touch screen device of claim 2, wherein the touch screen device includes a display device, and wherein the first region corresponds to a display region and the second region corresponds to a non-display region.

6. The touch screen device of claim 1, wherein the protrusions have a polygonal, semicircular, or semi-elliptical shape.

7. The touch screen device of claim 1, wherein the photo solder resist layer includes a via hole to connect one of the conductive patterns to another wiring.

8. The touch screen device of claim 1, wherein the sensing electrodes and the driving electrodes are made of a transparent conductive material.

9. The touch screen device of claim 1, wherein the wirings deliver touch signals generated from the sensing electrodes or deliver driving signals to the driving electrodes.

10. The touch screen device of claim 1, wherein the conductive patterns includes a combination of bars and patches.

11. A method of manufacturing a touch screen device having a wiring substrate, the method comprising:
forming a plurality of conductive patterns on a surface of a substrate, the plurality of conductive patterns including a plurality of sensing electrodes, a plurality of driving electrodes and a plurality of wirings connected to at least one of the plurality of sensing electrodes and the plurality of driving electrodes; and
forming a photo solder resist layer on the surface of the substrate, the photo solder resist layer including a body and a plurality of protrusions extending from a side of the body,
wherein an end portion of each protrusion is formed on each of the respective wirings, and a width of the end portion is smaller than a width of a starting portion of each protrusion that is in contact with the side of the body.

12. The method of claim 11, wherein the surface of the substrate comprises a first region located in a center portion of the substrate and a second region located in a periphery of the first region, and wherein the photo solder resist layer is formed on the second region.

13. The method of claim 12, further comprising forming a printed layer on the second region of the substrate, wherein the forming of the printed layer comprises placing the end portion of each protrusion on the printed layer.

14. The method of claim 11, wherein the protrusions have a polygonal, semicircular, or semi-elliptical shape.

15. The method of claim 11, wherein forming the photo solder resist layer includes forming a via hole in the photo solder resist layer to connect one of the conductive patterns to another wiring.

16. The method of claim 11, wherein the sensing electrodes and the driving electrodes are formed of a transparent conductive material.

17. The method of claim 11, wherein the wirings deliver touch signals generated from the sensing electrodes or deliver driving signals to the driving electrodes.

18. The method of claim 11, wherein the conductive patterns includes a combination of bars and patches.

19. The method of claim 11, wherein the forming the photo solder resist layer includes coating a photo solder resist ink on the surface of the substrate and irradiating a UV light on the coated photo solder resist ink.

20. The method of claim 19, wherein the forming the photo solder resist layer includes performing a process for removing portions of the photo solder resist ink that are not polymerized with the UV light.

21. A wiring substrate comprising:
a substrate;
a plurality of conductive patterns on a surface of the substrate; and
a photo solder resist layer on the surface of the substrate, the photo solder resist layer including a body and a plurality of protrusions extending from a side of the body,
wherein an end portion of each protrusion is formed on each of the conductive patterns, and a width of the end portion is smaller than a width of a starting portion of each protrusion that is in contact with the side of the body.
